(19) United States
(12) Patent Application Publication
(10) Pub. No.: US 2011/0057557 A1
(43) Pub. Date: Mar. 10, 2011

(54) PROJECTION LED MODULE AND METHOD OF MAKING A PROJECTION LED MODULE

(75) Inventors: Yong Chi, Shenzhen (CN); Shou Lung Chen, Ma On Shan (HK); Weiping Tang, Shenzhen (CN)

(73) Assignee: Hong Kong Applied Science and Technology Research Institute Co. Ltd., Shatin (HK)

(21) Appl. No.: 12/555,327

(22) Filed: Sep. 8, 2009

(51) Int. Cl. H01L 33/60; H01J 9/00

(52) U.S. Cl. 313/499; 445/22

(57) ABSTRACT

A projection light emitting diode (LED) module is provided. According to one embodiment, the LED module converts LED light to polarized light and emits the polarized light. One embodiments of the LED module includes a reflective polarizer positioned in a light emission path of the LED light, wherein the reflective polarizer polarizes the LED light, and the reflective polarizer further transmits the first polarization state light and reflects the second polarization state light; and a polarization conversion element bonded to the reflective polarizer, the polarization conversion element positioned between the LED light and the reflective polarizer, wherein the polarization conversion element coverts the second polarization state light to a desired polarization state light. A reflecting cup may be provided to increase the reflection of light back through the polarization conversion element and the reflective polarizer. The LED module may be configured for use with commercially available LED packages.

### FIELD OF THE INVENTION

The present invention relates to a light emitting diode module, and more particularly, to a projection light emitting diode module for emitting polarized light.

### BACKGROUND OF THE INVENTION

Advances in high-brightness light emitting diodes (LED) have created opportunities for the use of LED in different lighting technologies, including pico projectors. Light from the LED is projected onto a micro-display, such as a liquid crystal display (LCD), liquid crystal on silicon (LCoS) or digital micro-mirror device (DMD). One challenge of the pico-projector technology is that the light is typically polarized in LCD or LCoS applications. However, in polarizing LED light, a large part of the light source is wasted since one polarization state is absorbed, scattered, and/or blocked. Additionally, existing pico projectors may include a large number of separate components, resulting in a higher cost and larger device size.

Therefore, existing projection LED modules have these and other limitations. Accordingly, there is a need for an LED module that solves these and other shortcomings.

### SUMMARY OF THE INVENTION

According to one embodiment of the present invention, a projection light emitting diode (LED) module for converting LED light to polarized light and emitting the polarized light is disclosed. The LED module includes a reflective polarizer positioned in a light emission path of the LED light, wherein the reflective polarizer is configured to polarize the LED light, and the reflective polarizer further transmits first polarization state light and reflects second polarization state light; and a polarization conversion element bonded to the reflective polarizer, the polarization conversion element positioned between the LED light and the reflective polarizer, wherein the polarization conversion element coverts the second polarization state light to desired polarization state light.

According to another embodiment of the present invention, a projection light emitting diode (LED) module for converting LED light to polarized light and emitting the polarized light is disclosed. The LED module includes a substrate, one surface of the substrate defining a reflecting cup; an LED chip bonded to the substrate, the LED chip configured to emit a light beam; a reflective polarizer positioned in a light emission path of the light beam, wherein the reflective polarizer polarizes the light beam and transmits first polarization state light and reflects second polarization state light; and a polarization conversion element located on the substrate, the polarization conversion element positioned between the LED chip and the reflective polarizer, wherein the polarization conversion element is configured to convert the second polarization state light to desired polarization state light, and wherein the bonding of the polarization conversion element to the substrate defines an air gap adjacent to the LED chip, wherein the air gap is configured to narrow the light beam.

According to yet another embodiment of the present invention, a method of making a projection light emitting diode (LED) module is disclosed. The method includes the steps of providing a substrate, one surface of the substrate defining a reflecting cup; bonding an LED chip bonded to the substrate, the LED chip configured to emit a light beam; positioning a reflective polarizer in a light emission path of the light beam, wherein the reflective polarizer polarizes the light beam and transmits first polarization state light and reflects second polarization state light; and positioning a polarization conversion on the substrate between the LED chip and the reflective polarizer, wherein the polarization conversion element coverts the second polarization state light to desired polarization state light, and wherein the bonding of the polarization conversion element to the substrate defines an air gap adjacent to the LED chip.

Still other embodiments of the present invention will become readily apparent to those skilled in the art from the following detailed description, wherein embodiments of the invention are described by way of illustration. As will be realized, the invention is capable of other and different embodiments and its several details are capable of modifications in various respects, all without departing from the spirit and the scope of the present invention.

### BRIEF DESCRIPTION OF THE DRAWINGS

FIG. 1 is a perspective, cross sectional view of a light emitting diode (LED) module, in accordance with an embodiment of the present invention.

FIG. 2 is a side, cross sectional view of the LED module showing light reflection paths, in accordance with an embodiment of the present invention.

FIG. 3A is a side, cross sectional view of the LED module showing a spherical reflector shape, in accordance with an embodiment of the present invention.

FIG. 3B is a graph illustrating LED position and reflection path for the spherical reflector shape, in accordance with an embodiment of the present invention.

FIG. 4A is a side, cross sectional view of the LED module showing a parabolic reflector shape, in accordance with an embodiment of the present invention.

FIG. 4B is a graph illustrating LED position and reflection path for the parabolic reflector shape, in accordance with an embodiment of the present invention.

FIG. 5A is a side, cross sectional view of the LED module showing an elliptical reflector shape, in accordance with an embodiment of the present invention.

FIG. 5B is a graph illustrating LED position and reflection path for the elliptical reflector shape, in accordance with an embodiment of the present invention.

FIG. 6 is an LED module production process flow, in accordance with an embodiment of the present invention.

FIG. 7A is an exploded, perspective view of a first example LED module, including a compounded frame mount, in accordance with an embodiment of the present invention.

FIG. 7B is a side, cross sectional view of the first example LED module shown in FIG. 7A, in accordance with an embodiment of the present invention.

FIG. 8A is an exploded, perspective view of a second example LED module, including a LED chip on an MCPCB, in accordance with an embodiment of the present invention.

FIG. 8B is a side, cross sectional view of the second example LED module shown in FIG. 8A, in accordance with an embodiment of the present invention.

FIG. 9A is an exploded, perspective view of a third example LED module, including a commercial LED package, in accordance with an embodiment of the present invention.

FIG. 9B is a side, cross sectional view of the third example LED module shown in FIG. 9A, in accordance with an embodiment of the present invention.

FIG. 10A is an exploded, perspective view of a fourth example LED module, including a commercial LED package, in accordance with an embodiment of the present invention.

FIG. 10B is a side, cross sectional view of the fourth example LED module shown in FIG. 10A, in accordance with an embodiment of the present invention.

FIG. 11A is an exploded, perspective view of a fifth example LED module, including a commercial LED package, in accordance with an embodiment of the present invention.

FIG. 11B is a side, cross sectional view of the fifth example LED module shown in FIG. 11A, in accordance with an embodiment of the present invention.

FIG. 12 is a perspective view of a sixth example LED module, including a compounded frame mount without the lens, in accordance with an embodiment of the present invention.

FIG. 13 a perspective view of a seventh example LED module, including a commercial LED package without the lens, in accordance with an embodiment of the present invention.

FIG. 14A is a side cross sectional view of a projection system including the LED module, according to an embodiment of the present invention.

FIG. 14B is an exploded, perspective view of the projection system shown in FIG. 14A, according to an embodiment of the present invention.

FIG. 15 is a schematic diagram illustrating the LED module and generated light paths, according to an embodiment of the present invention.

FIG. 16 is a distribution plot showing the beam angle of the LED module, according to an embodiment of the present invention.

### DETAILED DESCRIPTION

In the following description, reference is made to the accompanying drawings where, by way of illustration, specific embodiments of the invention are shown. It is to be understood that other embodiments may be used as structural and other changes may be made without departing from the scope of the present invention. Also, the various embodiments and aspects from each of the various embodiments may be used in any suitable combinations. Accordingly, the drawings and detailed description are to be regarded as illustrative in nature and not as restrictive.

Generally, embodiments of the present invention are directed to an LED module that provides a polarizing system, a light recycling system, a condenser system, and thermal management. The LED module may be used to provide polarized light output without necessarily having an extended polarizing device in liquid crystal on silicon (LCoS) and liquid crystal display (LCD) projection systems. The light recycling system includes reflection and conversion of a first polarization state to the second polarization state. With the recycling system, more than half of the light from the light source LED chip can be outputted, thereby enhancing the optical efficiency and increasing the output brightness of a system incorporating the LED module. Additionally, embodiments of the present invention may generate a narrower viewing angle and a lower thermal resistance.

Referring now to the figures, FIG. 1 is a perspective, cross sectional view of a light emitting diode (LED) module 100, in accordance with an embodiment of the present invention. The LED module 100 includes a plurality of layers to provide a polarizing system, a light recycling system, a condenser system, and thermal management. The LED module 100 includes an LED chip 102 bonded on a substrate 104. A cup 106 is formed by the substrate 104. The cup 106 may have a reflector or reflective layer on the surface of the cup 106. Therefore, the cup 106 or the reflector on the surface of the cup 106 may be referred to as a reflecting cup. A quarter wave plate (QWP) layer 108 is formed over the LED chip 102 on the substrate 104. A reflective polarization layer 110 is positioned on the QWP layer 108. A lens 112 is applied over the reflective polarization layer 110 and may also further enclose the LED module 100. According to an embodiment of the present invention, an air gap 114 is formed between the LED chip 102 and the QWP layer 108.

The reflective polarization layer 110 is configured to transmit first polarization state light and reflect the second polarization state light back toward the substrate 104. The reflective polarization layer 110 may be any suitable type of polarizer such as, for example, a wire grid polarizer or a multilayer optical stack film. The QWP layer 108 is a polarization conversion element, or polarization shifter, that converts the second polarization state into a desired polarization state. The desired polarization state is effectively similar to the first polarization state. Therefore, once the second polarization state light has been converted into the first polarization state light, the light is transmitted by the reflective polarization layer 110. Suitable QWP layers 108 are known to those of skill in the art.

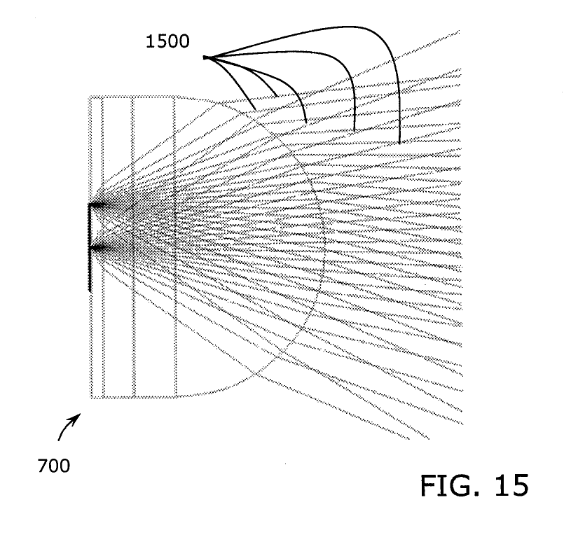

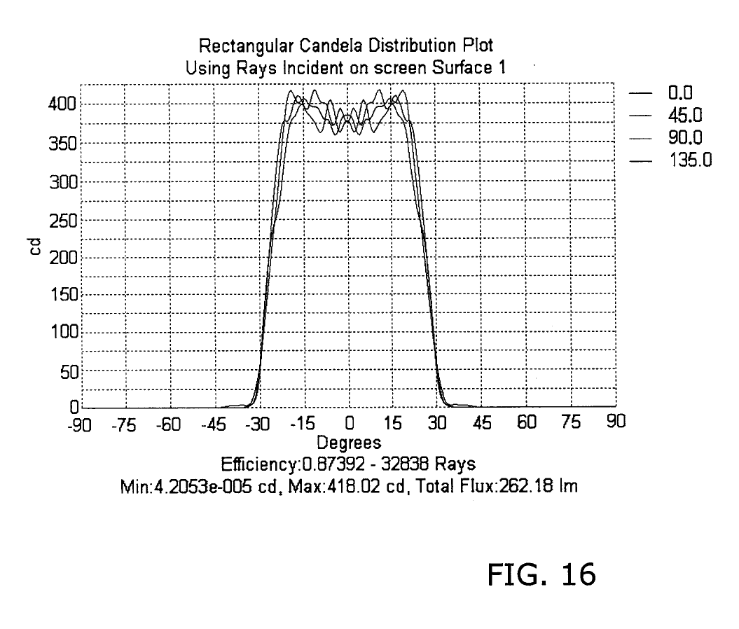

The air gap 114 may be provided to narrow the beam angle as light from the LED chip 102 is reflected into the QWP layer 108. Without the air gap 114, or if the air gap is filled with silicone or epoxy, the beam angle of the light emitted from the LED chip 102 may be larger than that provided using embodiments of the present invention. With the air gap 114, the beam angle is narrower and the resulting emitted light is more focused, as shown in FIG. 15-16.

The LED chip 102 may be any suitable LED device, such as either a single LED chip or a multi-chip LED. The substrate 104 is any suitable substrate for carrying an LED chip, such as silicon, ceramic, metal core printed circuit board (MCPCB), or other circuit board, where improved heat dissipation by reducing the thermal resistance between the LED chip 102 and the outside is desired. The lens 112 is any suitable lens such as, for example, PMMA, epoxy, glass, and etc.

In operation, the LED chip 102 emits light having both p-polarization and s-polarization. The reflective polarization layer 110 allows p-polarized light to be emitted through the lens 112 and reflects s-polarized light back toward the substrate 104. If s-polarized light is translated a quarter wavelength twice, then it is converted into p-polarized light. Therefore, when s-polarized light passes through the QWP layer 108 a first time when emitted from the LED chip 102, and after reflection by the reflective polarization layer 110, the s-polarized light is reflected by the cup 106 and passes through the QWP layer 108 a second time. After passage through the QWP layer 108 the second time, the s-polarized light is converted into p-polarized light and is then emitted through the lens 112. The emission of the p-polarized light that is converted from s-polarized light increases the total light output and energy of the LED module 100.

According to one embodiment of the present invention, the first polarization state light is p-polarized light, the second polarization state light is the s-polarized light, and the desired polarization state light is p-polarized light that has been converted from s-polarized light to p-polarized light.

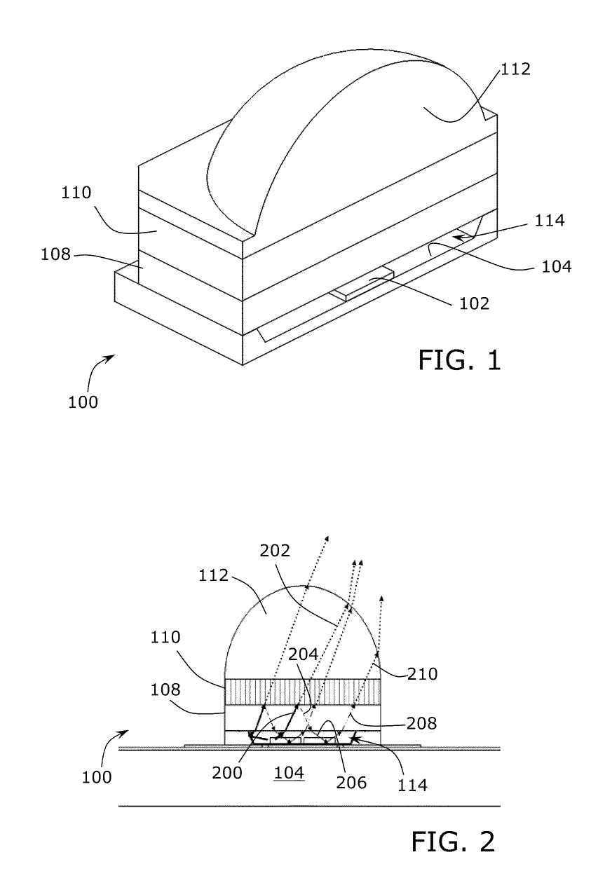

FIG. 2 is a side, cross sectional view of the LED module 100 showing light reflection paths, in accordance with an embodiment of the present invention. A legend shows the various types of light being passes through the LED module 100. Referring to one example light path, LED light 200 is emitted from the LED chip 102. A part of the LED light 200 is emitted through the reflective polarization layer 110 as p-polarized light 202. A part of the LED light 200 is reflected back as s-polarized light 204. The s-polarized light 204 is circularly reflected as once shifted light 206 and then as twice shifted light 208 before being emitted from the reflective polarization layer 110 as p-polarized light 210.

One advantage of embodiments of the present invention is that both large angle and small angle light is reflected out of the LED module 100. The configuration of the LED chip 102 and the shape of the cup 106 with reflector may reflect both large angle and small angle light, thereby increasing the amount of light emitted by the LED module 100.

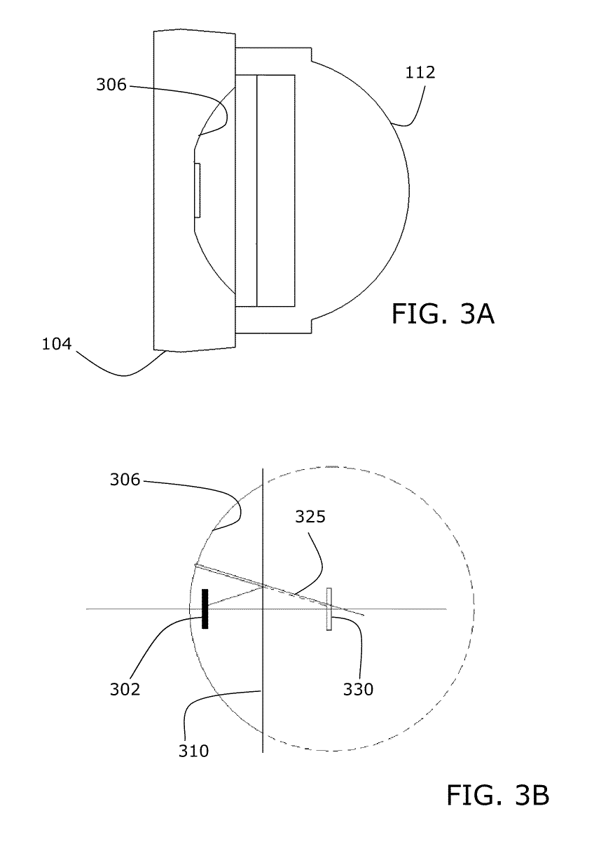

Referring now to FIGS. 3A to 5B, three different cup shapes and associated LED chip position and reflection path graphs are illustrated. The surface of the cup has a reflector to increase the reflection of the light from the LED chip. By choosing a position of the LED chip that complements the reflector shape, an increased amount of light can be emitted from the LED module 100 by considering the light path of light reflected by the particular cup shape. In conventional LED packages, the shape of the substrate is not configured for optimal reflection. By specifically configuring the shape of the substrate and the position of the LED chip on the substrate, a recycled light path can be controlled and predetermined similar to the original light path so that a greater amount of light is recycled and can pass through the projection. If the recycled light path is not similar to the original light path, even the reflected light is recycled but it can not pass through the projection system because the projection optical design is based on the original LED chip position and size.

FIG. 3A is a side, cross sectional view of the LED module showing a spherical reflector shape, and FIG. 3B is a graph illustrating LED position and reflection path for the spherical reflector shape. A reflector 306 is located on the substrate 104, the substrate 104 or the reflector 306, or both the substrate 104 and the reflector 306, having a generally spherical shaped curve. The LED chip 302 is located on the surface of the substrate 104. Recycled light rays 325 are reflected by the reflective polarization layer 310, and then the reflector 306, and a chip image 330 is formed generally at a location that would be the center of the sphere shaped curve.

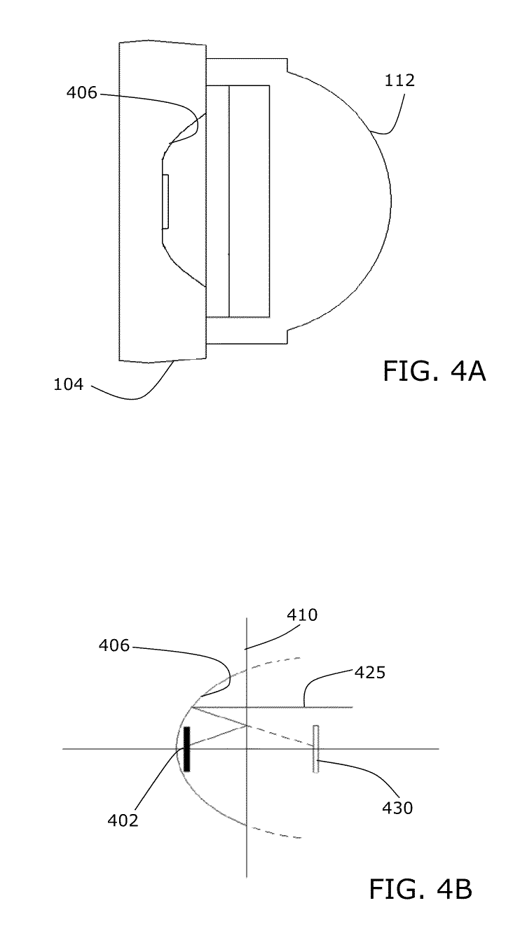

FIG. 4A is a side, cross sectional view of the LED module showing a parabolic reflector shape, and FIG. 4B is a graph illustrating LED position and reflection path for the parabolic reflector shape. A reflector 406 is located on the substrate 104, the substrate 104 or the reflector 406, or both the substrate 104 and the reflector 406, having a generally parabolic shaped curve. The LED chip 402 is located generally at the vertex of the reflector 406. Recycled light rays 425 are reflected by the reflector 406 and passed through the reflective polarization layer 410 substantially orthogonally. A chip image 430 is formed generally at a location that would be the focus of the parabolic reflector.

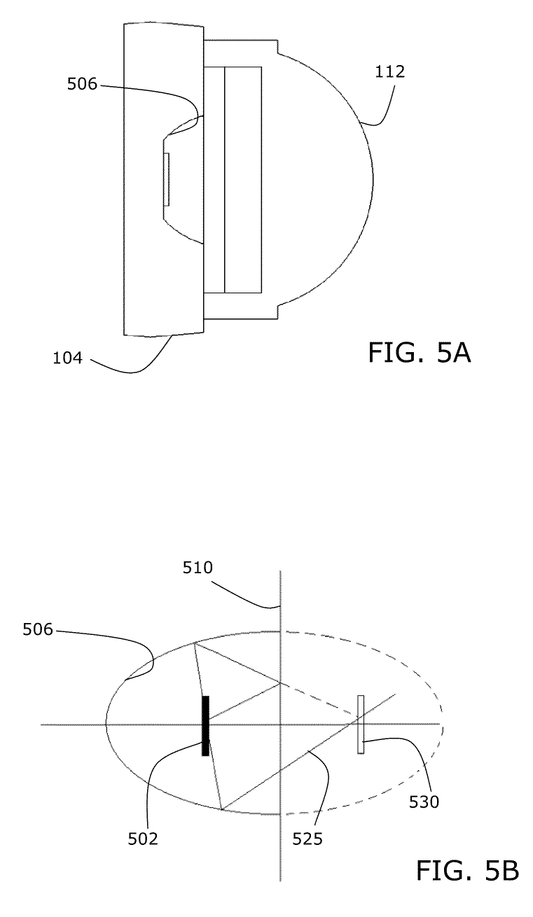

FIG. 5A is a side, cross sectional view of the LED module showing an elliptical reflector shape, and FIG. 5B is a graph illustrating LED position and reflection path for the elliptical reflector shape. A reflector 506 is located on the substrate 104, the substrate 104 or the reflector 506, or both the substrate 104 and the reflector 506, having a generally elliptical shaped curve. The LED chip 502 is located at a first focus of the elliptical shape, proximate to the reflector 506. Recycled light rays 525 are first reflected by the reflective polarization layer 510 towards the LED chip 502 and then reflected at a second part of the reflector 506, then forming a chip image 530 generally at a location that would be a second focus of the elliptical shape.

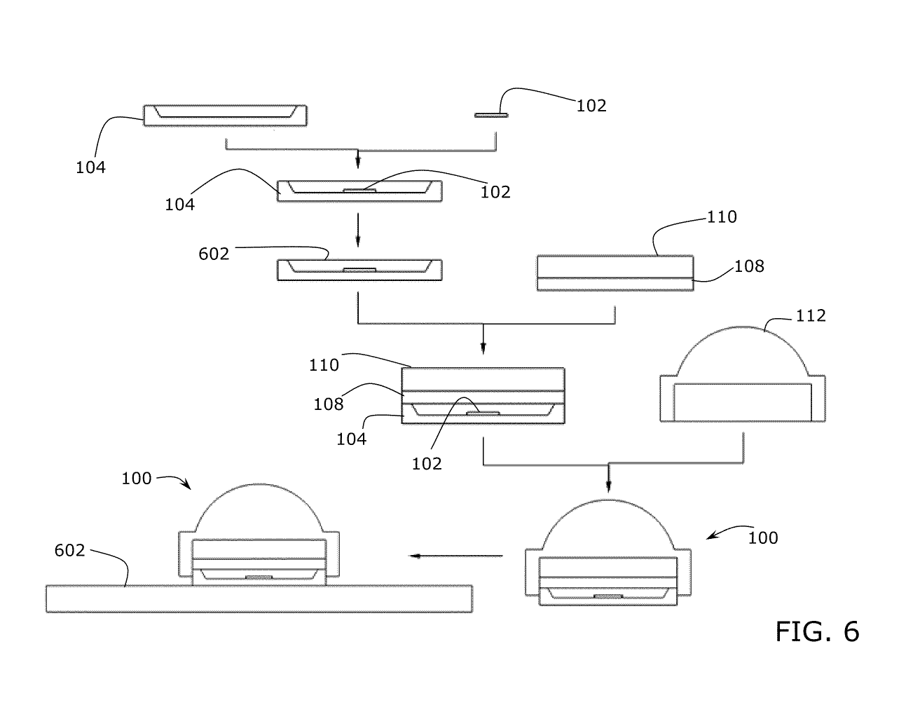

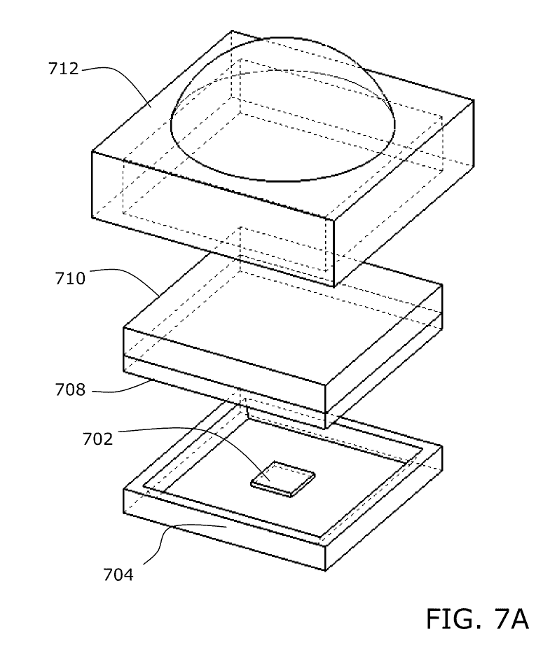

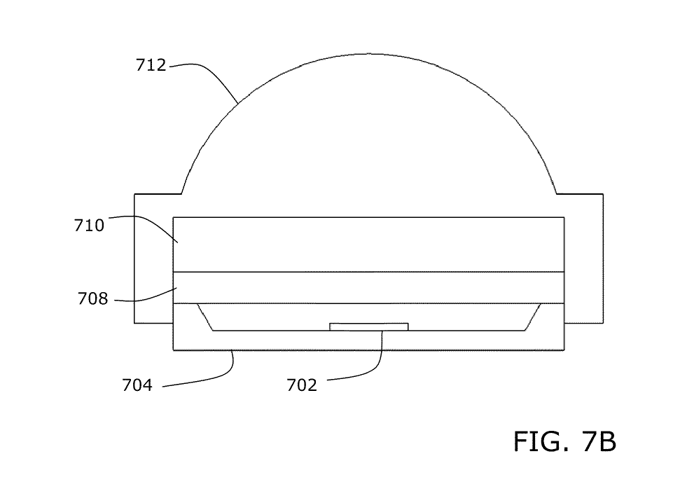

FIG. 6 is an LED module production process flow, in accordance with an embodiment of the present invention. In a first step, a substrate 104 is provided, the substrate 104 having a cup formed into the surface, and an LED chip 102 is provided. Then, the LED chip 102 is attached to the substrate 104 by LED and wire bonding. In one embodiment, after the LED and wire bonding, a silicon 602 filling process may be included. In another step, the reflective polarization layer 110 and the QWP layer 108 are joined. The QWP layer 108 and the reflective polarization layer 110 are then placed on the substrate 104. The lens 112 covers the reflective polarization layer 110 and the QWP layer 108 then is joined to substrate 104, thereby forming the LED module 100, in accordance with an embodiment of the present invention. The LED module 100 may then be surface mounted, for example, onto a MCPCB or PCB 600. While these process steps are described in a particular order, other fabrication orders and processes may be used. Therefore, the above steps illustrate one example fabrication process.

Referring now to FIGS. 7A to 10B, examples of LED modules made in accordance with embodiments of the present invention are illustrated in described. The description with reference to FIGS. 1 to 6 similarly applies to the examples shown and described with reference to FIGS. 7 to 10.

FIG. 7A is an exploded, perspective view of a first example LED module, including a compounded frame mount, in accordance with an embodiment of the present invention. Three separate components are provided and combined to form an LED module 700 including: (1) an LED chip 702 formed on a substrate 704; (2) a QWP layer 708 and a reflective polarization layer 710 bonded together; and (3) a lens 712. The lens 712 maybe be a combination of a lens with a lens cube defining a hollow on one side of the lens 712. The reflective polarization layer 710 and the QWP layer 708 may be positioned in the hollow, and then the lens 712 together with the QWP layer 708 and the reflective polarization layer 710 are joined to the substrate.

FIG. 7B is a side, cross sectional view of the first example LED module shown in FIG. 7A, in accordance with an embodiment of the present invention. A reflective cup 714 is shown formed in the substrate 704. The lens 712 surrounds the substrate 704 when joined to for the LED module 700.

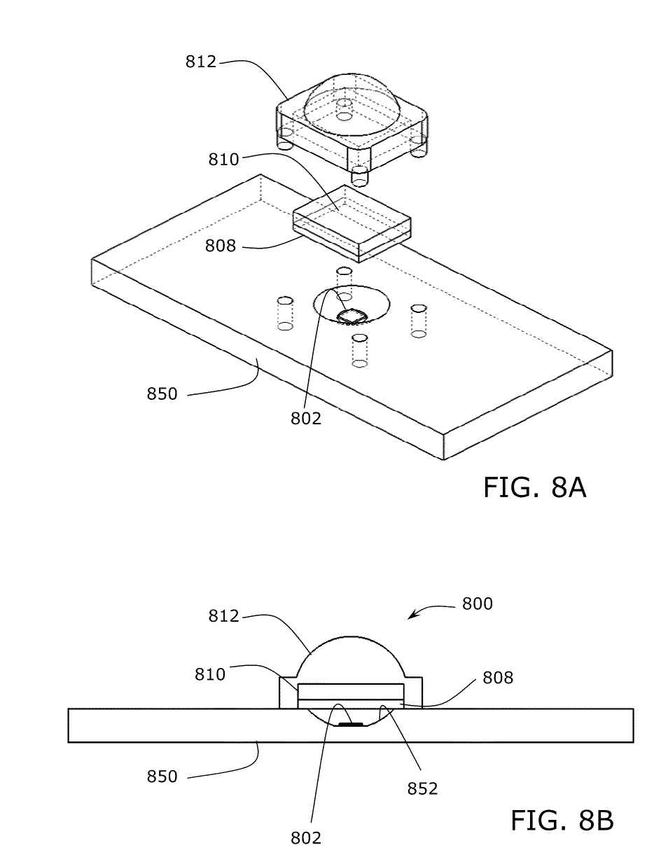

FIG. 8A is an exploded, perspective view of a second example LED module 800, including a LED chip on a MCPCB 850, in accordance with an embodiment of the present invention. The mounting of the LED chip 802 direct on the MCPCB 850 may result in for lower thermal resistance. Three separate components are provided and combined to form an LED module 800 including: (1) an LED chip 802 direct bonded on a MCPCB 850; (2) a QWP layer 808 and a reflective polarization layer 810 bonded together; and (3) a lens 812. The lens 812 maybe be a combination of a lens with a lens cube defining a hollow on one side of the lens. The reflective polarization layer 810 and the QWP 808 layer may be positioned in the hollow, and then the lens together with the QWP layer 808 and the reflective polarization layer 810 are joined to the MCPCB 850.

FIG. 8B is a side, cross sectional view of the second example LED module shown in FIG. 8A, in accordance with an embodiment of the present invention. A reflective cup 852 is shown formed in the MCPCB. The lens 812 surrounds the QWP 808 layer and reflective polarization layer 810 when fixed on the MCPCB 850.

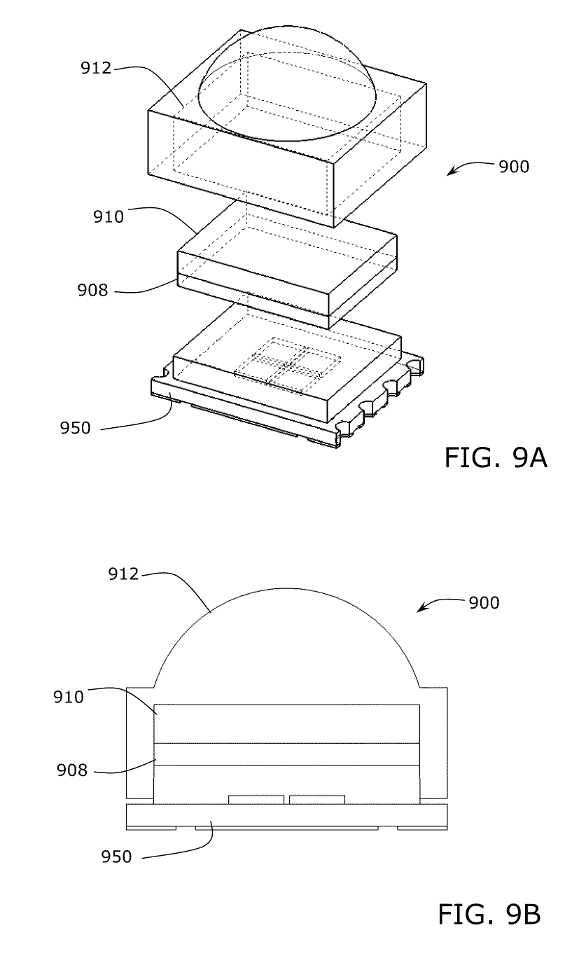

FIG. 9A is an exploded, perspective view of a third example LED module 900, including a commercial LED package, in accordance with an embodiment of the present invention. Two separate components are provided and combined to form an LED module 900 including: (1) a QWP layer 908 and a reflective polarization layer 910 bonded together, and (2) a lens 912. The LED module 900 may then be sealed onto any suitable, commercial available LED package 950. In one embodiment, the LED package 950 includes a reflective cup configured in accordance with embodiments of the present invention to provide increased reflection of light from the LED chip. In another embodiment, the LED package 950 is a multi-LED package, such as an RGB LED package.

FIG. 9B is a side, cross sectional view of the third example LED module shown in FIG. 9A, in accordance with an embodiment of the present invention. The LED module 900 is shown sealed to the LED package 950.

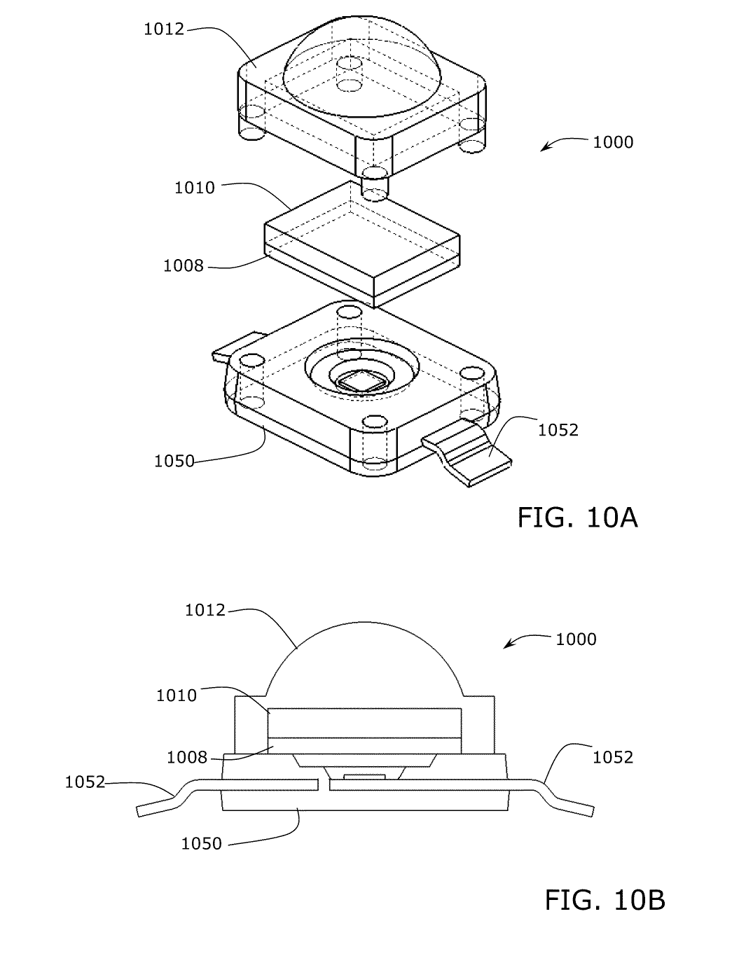

FIG. 10A is an exploded, perspective view of a fourth example LED module, including a commercial LED package, in accordance with an embodiment of the present invention. Two separate components are provided and combined to form an LED module 1000 including: (1) a QWP layer 1008 and a reflective polarization layer 1010 bonded together, and (2) a lens 1012. The LED module 1000 may then be sealed onto any suitable, commercial available LED package 1050. In one embodiment, the LED package 1050 includes a reflective cup configured in accordance with embodiments of the present invention to provide increased reflection of light from the LED chip.

FIG. 10B is side, cross sectional view of the fourth example LED module shown in FIG. 10A, in accordance with an embodiment of the present invention. The LED module 1000 is shown sealed to the LED package 1050. The LED package 1050 includes wires 1052 for electrical coupling with a circuit for operation.

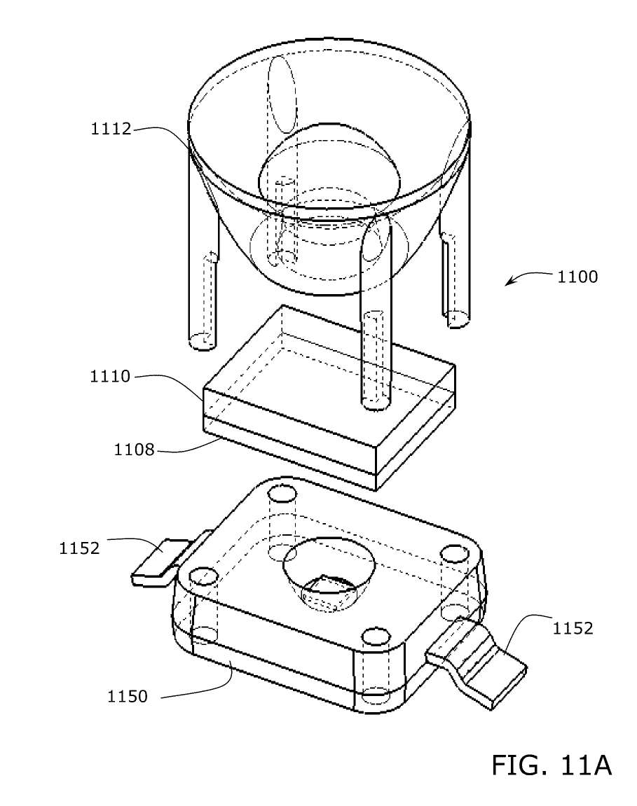

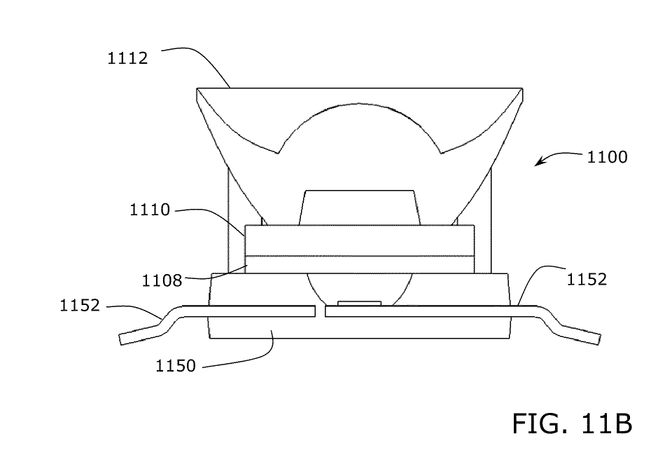

FIG. 11A is an exploded, perspective view of a fifth example LED module, including a commercial LED package, in accordance with an embodiment of the present invention. Two separate components are provided and combined to form an LED module 1100 including: (1) a QWP layer 1108 and a reflective polarization layer 1110 bonded together, and (2) a lens total internal reflection (TIR) lens 1112. The LED module 1100 may then be sealed onto any suitable, commercial available LED package 1150. In one embodiment, the LED package 1150 includes a reflective cup configured in accordance with embodiments of the present invention to provide increased reflection of light from the LED chip.

FIG. 11B is side, cross sectional view of the fifth example LED module shown in FIG. 11A, in accordance with an embodiment of the present invention. The LED module 1100 is shown sealed to the LED package 1150. The LED package 1150 includes wires 1152 for electrical coupling with a circuit for operation.

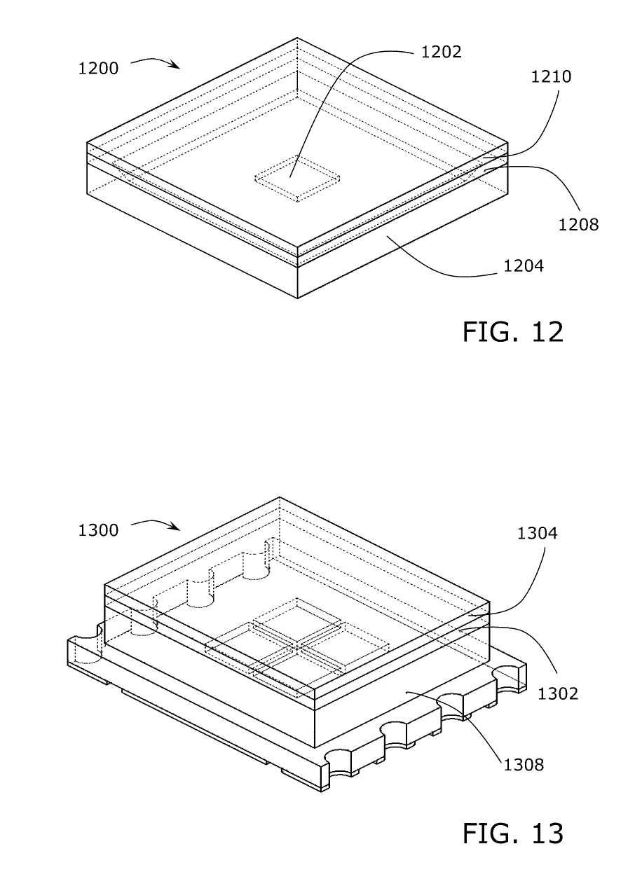

FIG. 12 is a perspective view of a sixth example LED module, including a compounded frame mount without the lens, in accordance with an embodiment of the present invention. The LED module 1200 includes an LED chip 1202 bonded on a substrate 1204, a QWP layer 1208 and a reflective polarization layer 1210 affixed together. Then the QWP layer 1208 with the reflective polarization layer 1210 affixed on the substrate 1204 to seal the LED Chip 1202.

FIG. 13 a perspective view of a seventh example LED module, including a commercial LED package without the lens, in accordance with an embodiment of the present invention. A QWP layer 1302 and a reflective polarization layer 1304 are affixed together. The QWP layer 1208 with the reflective polarization layer 1210 can then be affixed onto any suitable, commercial LED package 1308 with a generally flat package surface for emitting light.

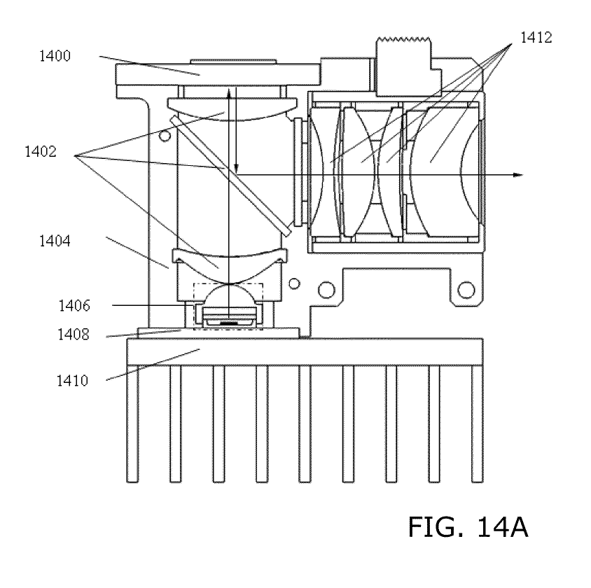

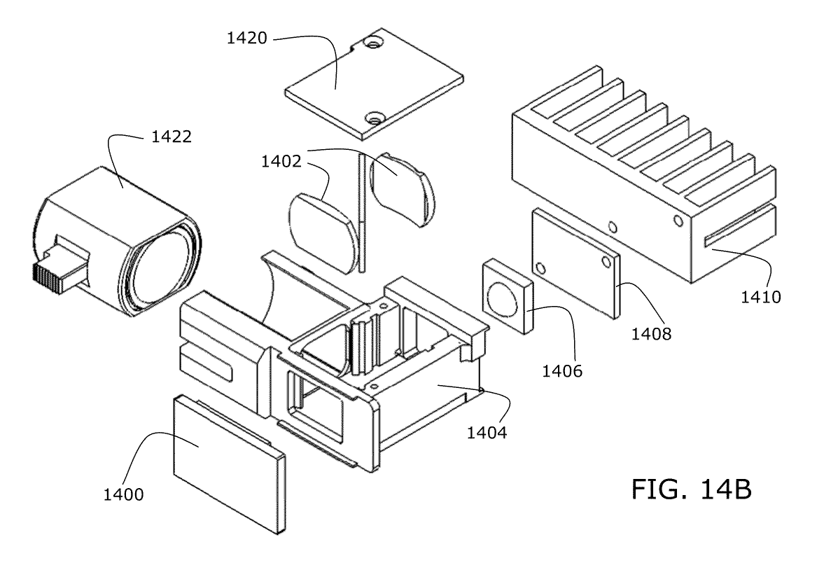

Referring to FIGS. 14A and 14B, FIG. 14A is a side cross sectional view of a projection system including the LED module, and FIG. 14B is an exploded, perspective view of the projection system illustrated in FIG. 14A, according to an embodiment of the present invention. The LED module 1406 is bonded to an MCPCB 1408, and a heat sink 1410 is attached to the back side of the MCPCB 1408 so that the heat from the LED chip in the LED module 1406 can be dissipated. Then the LED module 1406 and the MCPCB are coupled to a housing 1404. Several optical components 1402 may be positioned in the optical path and secured by the housing 1404 and cover 1420. An LCoS panel 1400 is attached to the housing 1404 opposite to the LED module 1406. Some projection lenses 1412 may be positioned in a cylinder 1422 which can slide within the housing for adjusting the focus. The light rays emitted from LED module 1406 transmit through the optical components 1402 then reach the LCoS panel 1400. After reflected by the LCoS panel 1400 and optical components 1402, the light rays transmit through the projection lenses 1412 and then are projected out of the projection system. Due to polarizing and light recycling, the LED module 1406 can increase the total light output and energy of the projection system when compared to conventional projection systems.

FIG. 15 is a schematic diagram illustrating the LED module 700 and generated light paths, according to an embodiment of the present invention. The light paths, some of the light paths labeled with reference number 1500, are shown having a narrower light angle when compared to convention light modules where an air gap is not provided.

FIG. 16 is a distribution plot showing the beam angle of the LED module, according to an embodiment of the present invention. In the distribution plot, in order to match with the projection optical path, the beam angle is configured to 55°. For different projection optical engine, the beam angle of the LED module 700 can be changed to match with the projection optical engine by modify the lens shape, the reflective polarization thickness, the QWP thickness and the air gap thickness.

Embodiments of the present invention include a reflective polarization layer and a QWP layer inside of or under the lens. Therefore, embodiments of the present invention may permit smaller LED module design having similar brightness or increased brightness when compared to larger devices. Similarly, the beam angle is similar or improved when compared to larger devices. Embodiments of the present invention can also be used with a large output angle while maintaining a high level of efficiency.

While the invention has been particularly shown and described with reference to the illustrated embodiments, those skilled in the art will understand that changes in form and detail may be made without departing from the spirit and scope of the invention. For example, while specific component types have been indicated, other similar and suitable alternatives may also be used. Additionally, while embodiments of the present invention are well suited for use in LED micro-projectors and pico projectors, embodiments of the present invention may also be used for any other suitable applications.

Accordingly, the above description is intended to provide example embodiments of the present invention, and the scope of the present invention is not to be limited by the specific examples provided.

What is claimed is:

1. A projection light emitting diode (LED) module for converting LED light to polarized light and emitting the polarized light, the LED module comprising:
a reflective polarizer positioned in a light emission path of the LED light, wherein the reflective polarizer is configured to polarize the LED light, and the reflective polarizer further transmits first polarization state light and reflects second polarization state light; and
a polarization conversion element bonded to the reflective polarizer, the polarization conversion element positioned between the LED chip and the reflective polarizer, wherein the polarization conversion element coverts the second polarization state light to desired polarization state light.

2. The projection LED module of claim 1, wherein the polarization conversion element is a quarter wave plate, and wherein when the second polarization light passes twice through the quarter wave plate, the second polarization state light is converted into the desired polarization state light and emitted by the reflective polarizer.

3. The projection LED module of claim 1, further comprising a lens, wherein the lens is configured to enclose the reflective polarizer and the polarization conversion element, and wherein the lens, the reflective polarizer and the polarization conversion element are together configured for engagement with an LED package.

4. The projection LED module of claim 1, further comprising:
a substrate, one surface of the substrate defining a reflecting cup; and
at least one LED chip bonded to the substrate, the LED chip configured to emit the LED light, wherein the polarization element is bonded to the substrate.

5. The projection LED module of claim 4, wherein the bonding of the polarization conversion element to the substrate defines an air gap adjacent to the LED chip, wherein the air gap is configured to narrow the LED light prior to contact with the polarization conversion element.

6. The projection LED module of claim 4, wherein the reflecting cup has a partial spherical shaped curve, and the reflecting cup is configured to reflect the desired polarization state back in the direction of the polarization conversion element.

7. The projection LED module of claim 4, wherein the reflecting cup has a partial parabolic shaped curve, and the reflecting cup is configured to reflect the desired polarization state light back in the direction of the polarization conversion element.

8. The projection LED module of claim 4, wherein the reflecting cup has a partial elliptical shaped curve, and the reflecting cup is configured to reflect the desired polarization state back in the direction of the polarization conversion element.

9. The projection LED module of claim 4, wherein the reflecting cup is configured to reflect both large angle LED light and small angle LED light.

10. A projection light emitting diode (LED) module for outputting polarized light, the LED module comprising:
a substrate, one surface of the substrate defining a reflecting cup;
at least one LED chip bonded to the substrate, the LED chip configured to emit a light beam;
a reflective polarizer positioned in a light emission path of the light beam, wherein the reflective polarizer polarizes the light beam and transmits first polarization state light and reflects second polarization state light; and
a polarization conversion element located on the substrate, the polarization conversion element positioned between the LED chip and the reflective polarizer, wherein the polarization conversion element is configured to convert the second polarization state light to desired polarization state light, and wherein the bonding of the polarization conversion element to the substrate defines an air gap adjacent to the LED chip, wherein the air gap is configured to narrow the light beam.

11. The projection LED module of claim 10, wherein the polarization conversion element is a quarter wave plate, and wherein when the second polarization state light passes twice through the quarter wave plate, the second polarization state light is converted into desired polarization state light and emitted by the reflective polarizer.

12. The projection LED module of claim 10, further comprising a lens, wherein the lens is configured to enclose the reflective polarizer and the polarization conversion element, and wherein the lens, the reflective polarizer and the polarization conversion element are together configured for engagement with the substrate.

13. The projection LED module of claim 10, wherein the reflecting cup has a partial spherical shaped curve, and the reflecting cup is configured to reflect the desired polarization state light back in the direction of the polarization conversion element.

14. The projection LED module of claim 10, wherein the reflecting cup has a partial parabolic shaped curve, and the reflecting cup is configured to reflect the desired polarization state light back in the direction of the polarization conversion element.

15. The projection LED module of claim 10, wherein the reflecting cup has a partial elliptical shaped curve, and the reflecting cup is configured to reflect the desired polarization state light back in the direction of the polarization conversion element.

16. The projection LED module of claim 10, wherein the reflecting cup is configured to reflect both large angle LED light and small angle LED light.

17. A method of making a projection light emitting diode (LED) module comprising:
providing a substrate, one surface of the substrate defining a reflecting cup;
bonding at least one LED chip bonded to the substrate, the LED chip configured to emit a light beam;
positioning a reflective polarizer in a light emission path of the light beam, wherein the reflective polarizer polarizes the light beam and transmits first polarization state light and reflects second polarization state light; and
positioning a polarization conversion on the substrate between the LED chip and the reflective polarizer, wherein the polarization conversion element coverts the second polarization state light to desired polarization state light, and wherein the bonding of the polarization conversion element to the substrate defines an air gap adjacent to the LED chip.

18. The method of claim 17, further comprising:
defining an air gap between the polarization conversion element and the LED chip, the air gap configured to narrow the light beam.

19. The method of claim 17, wherein the polarization conversion element is a quarter wave plate, and wherein when the second polarization state light passes twice through the quarter wave plate, the second polarization state light is converted into desired polarization state light and emitted by the reflective polarizer.

20. The method of claim 19, wherein the reflecting cup has a partial spherical shaped curve, and the reflecting cup is configured to reflect the desired polarization state light back in the direction of the polarization conversion element.
